(19) United States
(12) Patent Application Publication
(10) Pub. No.: US 2016/0150667 A1
(43) Pub. Date: May 26, 2016

(54) SERVER

(71) Applicants: INVENTEC (PUDONG) TECHNOLOGY CORPORATION, SHANGHAI (CN); INVENTEC CORPORATION, TAIPEI CITY (TW)

(72) Inventors: Ji-Peng XU, Shanghai (CN); Ming-Gang Li, Shanghai (CN)

(21) Appl. No.: 14/616,762

(22) Filed: Feb. 9, 2015

(30) Foreign Application Priority Data
Nov. 26, 2014 (CN) 201410705503.9

(51) Int. Cl. H05K 7/14

(52) U.S. Cl. CPC H05K 7/1489; H05K 7/1491; H05K 7/1492

(57) ABSTRACT

A server is provided and disposed in a case, the server comprises a chassis divided to a storage area and a motherboard area by a partition plate, a storage module disposed in a front end of the storage area and plugged in an inner wall of the storage area, a motherboard module disposed in a front end of the motherboard area, an adapter board disposed in the motherboard area and electrically connected to the motherboard module a power supply board disposed in a rear end of the motherboard area and electrically connected to an external case power-supply, a signal board disposed in a rear end of the motherboard area and electrically connected to an external case controller, and a foldable cable management module comprising a foldable cable management shelf and a cable constrained in the foldable cable management shelf.

### FIELD OF THE INVENTION

The disclosure relates to a technical field of a server, and more particularly to a pluggable server.

### BACKGROUND

With the rapid development of servers, maintenance of servers has become a key area. Currently, a motherboard is disposed in the middle of the hard disk in the most of the servers, and the motherboard is connected to the hard disk by an adapter board. When the motherboard is repaired, the hard disk and the adapter board must be disassembled and then the motherboard is disassembled to be repaired; thus the process is cumbersome and complex, and the hard disk and the adapter board are easily damaged in the process. In addition, a power supply board and a signal board of the server are disengaged from a power-supply and a controller of the case when the server is pulled from a case. Therefore the transmission of the power and signal of the server is discontinued, and the server cannot be plugged in. A foldable cable must be disposed in the motherboard and the hard disk to avoid discontinuing the power and signal when the motherboard and the hard disk are removed. An adjustable cable is also disposed in the motherboard and the hard disk, a network cable is connected to the motherboard.

### SUMMARY

A primary object of the disclosure is to provide a server which is operated in a case, and a hard disk of the server can be plugged and removed.

To achieve the above object, the disclosure provides a server disposed in a case which comprises a chassis, a storage module, a motherboard module, an adapter board, a power supply board, a signal board, and a foldable cable management module. The chassis is divided to a storage area and a motherboard area by a partition plate. The storage module is disposed in a front end of the storage area and plugged in an inner wall of the storage area. The motherboard module is disposed in a front end of the motherboard area The adapter board is disposed in the motherboard area and electrically connects to the motherboard module. The power supply board is disposed in a rear end of the motherboard area and electrically connects to an external case power-supply for supplying power to the motherboard module and the storage module. The signal board is disposed in a rear end of the motherboard area and electrically connects to an external case controller for transmitting signals of the server. The foldable cable management module comprises a foldable cable management shelf and a cable constrained in the foldable cable management shelf, wherein an end of the foldable cable management shelf is connected to a rear end of the storage area, and another end of the foldable cable management shelf is connected to the storage module, an end of the cable is electrically connected to the storage module, and another end of the cable is electrically connected to the motherboard module and the adapter board. The foldable cable management shelf is folded or unfolded by plugging in the storage module.

### BRIEF DESCRIPTION OF THE DRAWINGS

FIG. 1 is an illustration of a server in accordance with an embodiment;

FIG. 2A is an illustration of a storage module of a server pulled in accordance with an embodiment;

FIG. 2B is an illustration of a storage module of a server pulled in accordance with an embodiment;

FIG. 3 is an illustration of a storage module in accordance with an embodiment

FIG. 4 is an illustration of a storage module removed in accordance with an embodiment;

FIG. 5 is an illustration of rails and grooves in accordance with an embodiment;

FIG. 6 is an illustration of the position A in FIG. 2A;

FIG. 7 is an illustration of the position B in FIG. 2A;

FIG. 8 is an illustration of a bottom of a storage module in accordance with an embodiment;

FIG. 9 is an illustration of an aspect of a box in accordance with an embodiment;

FIG. 10 is an illustration of another aspect of a box in accordance with an embodiment;

FIG. 11 is an illustration of a foldable cable management shelf folded in accordance with an embodiment; and

FIG. 12 is an illustration of a foldable cable management shelf unfolded in accordance with an embodiment.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

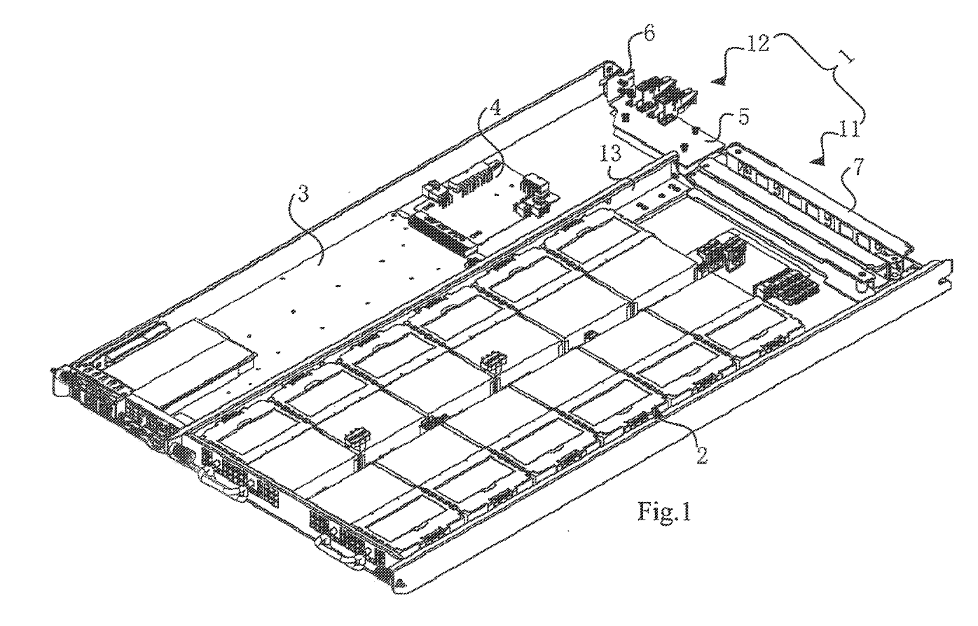

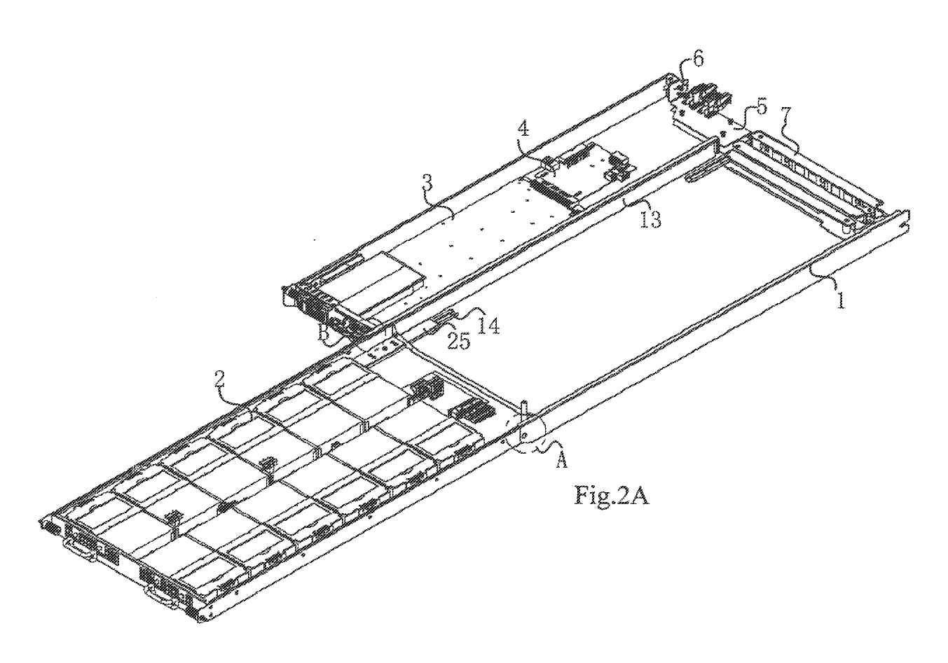

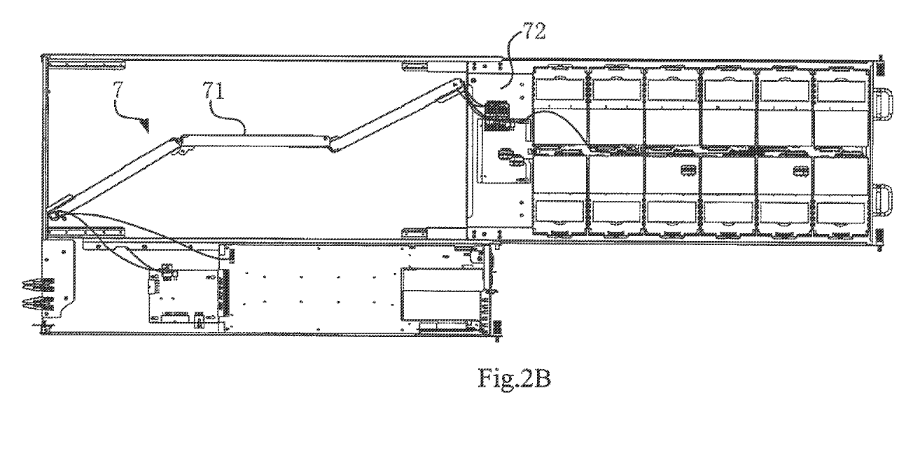

FIGS. 1 and 2A is an illustration of an embodiment of a server disposed in an external case. As the illustration, the server comprises a chassis 1, a storage module 2, a motherboard module 3, an adapter board 4, a power supply board 5, a signal board 6, and a foldable cable management module 7.

The chassis 1 is divided to a storage area 11 and a motherboard area 12 by a partition plate 13. In the optional embodiment, the storage area 11 and the motherboard area 12 are parallel, and the sizes of the storage area 11 and the motherboard area 12 are not limited according to the requirement of the user. Two sides of the front end of the chassis 1 are screwed on the case.

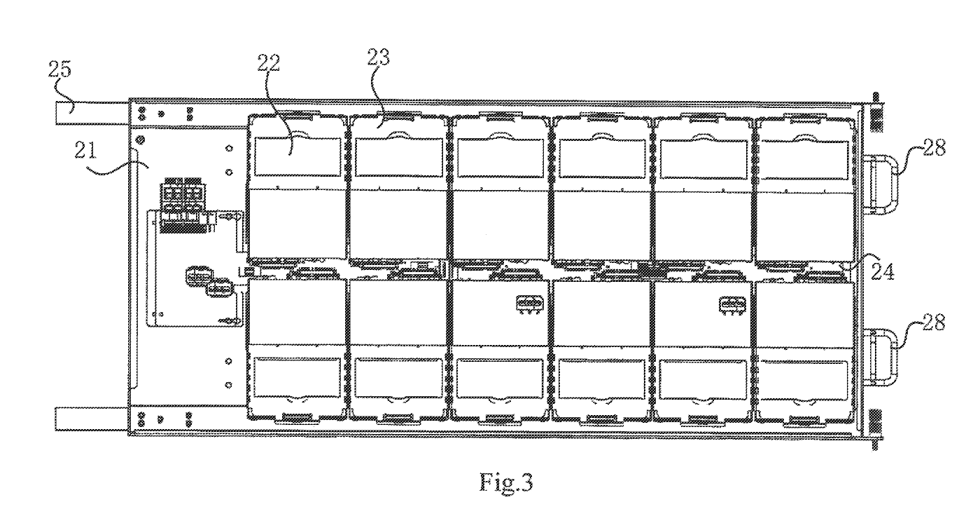

The storage module 2 is disposed in a front end of the storage area 11 and plugged in an inner wall of the storage area 11. The storage module 2 is a form of an independent drawer, and elements are not influenced from the repair of the storage module 2 for plugging the server. Referring to FIG. 3, the storage module 2 comprises a tray 21, a plurality of storage units 22, a plurality of storage boxes 23, and a storage backplane 24. The tray 21 is accommodated the storage units 22, the storage boxes 23 and the storage backplane 24. The storage boxes 23 are accommodated the storage units 22 respectively, and are disposed back to back in the tray 21. Thus, each of the storage units 22 is plugged from the storage backplane 24 by the storage boxes 23.

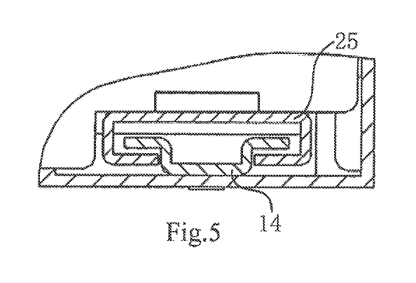

Referring to FIGS. 3, 4, and 5, a bottom of the tray 21 comprises two symmetrical grooves 25 positioned in two opposite sides relatively, and the storage area 11 of the chassis 1 comprises two rails 14. The chassis 1 is slid onto the grooves 25 by the rails 14. In the optional embodiment, the rails 14 are disposed on two opposite sides of the storage area 11 relatively. This can avoid having to dispose a traditional groove, thereby reducing costs. The grooves 25 and the rails 14 are screwed on the bottom of the tray 21 and the chassis 1 respectively. Moreover, a least one handle 28 is disposed in the front end of the storage module 2 for pulling the storage module 2, and the storage module 2 can be plugged in the storage area 11. In the optional embodiment, two handles 28 are disposed on the front end of the storage module 2.

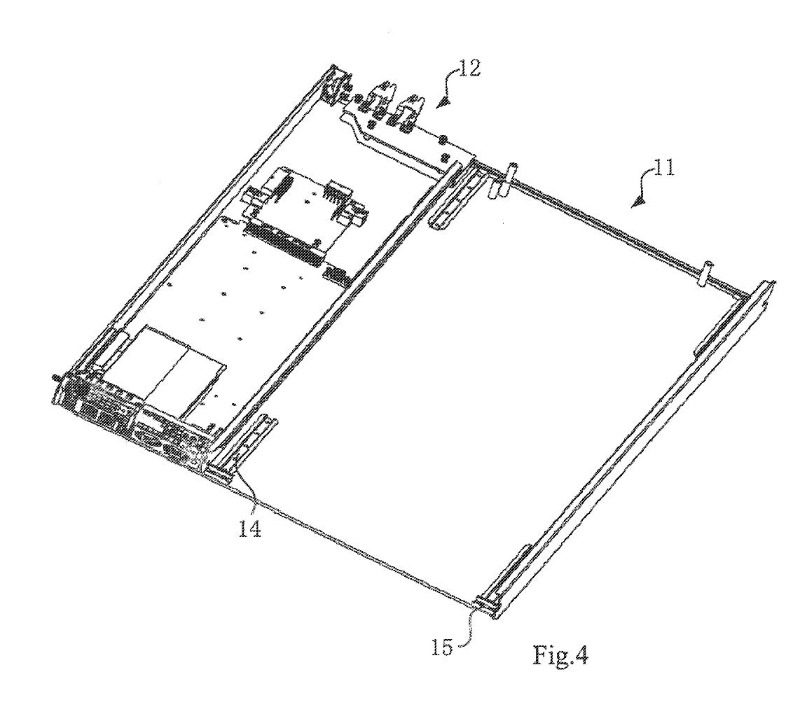

Referring to FIGS. 2A and 4, a plurality of elastic components 15 (such as rubber) are disposed on the front end or rear end of the bottom of the storage area 11 to buffer the storage module 2 when the storage module 2 is plugged in the storage area 11 by the grooves 25 and the rails 14. The storage module 2 is also plugged slowly by the elastic components 15. The elastic components 15 disposed on the front end of the bottom of the storage area 11 buffer the storage module 2 when the storage module 2 is pulled up along the rails 14. The elastic components 15 disposed on the rear end of the bottom of the storage area 11 buffer the storage module 2 when the storage module 2 is inserted into the storage area 11 along the rails 14. The advantages of the grooves 25 and the rails 14 are that there is sufficient strength to avoid the storage module 2 sinking and that they maintain the direction of the storage module 2.

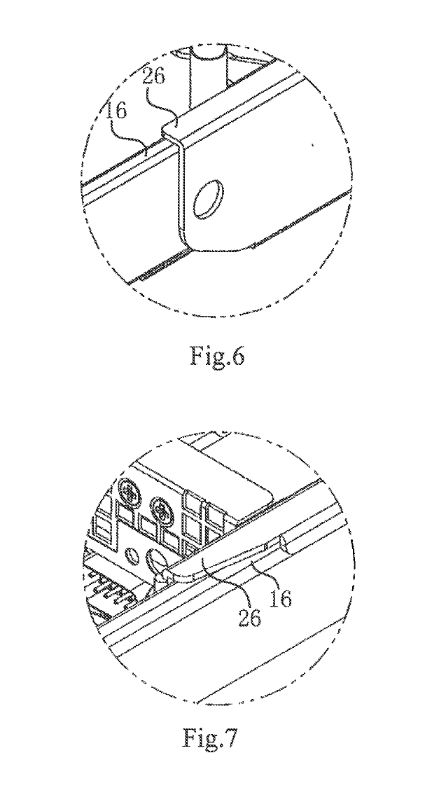

Referring to FIGS. 2A and 6, the tray 21 comprises a U-shaped guide rail 26, and the chassis 1 comprises a U-shaped guide channel 16 embedded with the U-shaped guide rail 26 near the storage area 11, so that the storage module 2 is plugged from the storage area 11. Referring to FIGS. 2A and 7, a U-shaped guide channel 16 is also disposed on the partition plate 13, and the U-shaped guide rail 26 is embedded with the U-shaped guide channel 16, The shape of the U-shaped guide channel 16 on the chassis 1 and the shape of the U-shaped guide channel 16 on the partition plate 13 are either the same or different, and are not limited in the disclosure. For example, the shape of the U-shaped guide channel 16 on the chassis 1 and the shape of the U-shaped guide channel 16 on the partition plate 13 are different in the optional embodiment; an initial end of the U-shaped guide channel 16 on the partition plate 13 is an L-shaped guide channel to provide the U-shaped guide rail 26 inserted. The U-shaped guide channel 16 of the storage area 11 and the U-shaped guide channel 16 of the partition plate 13 can be assembled with the U-shaped guide rail 26 of the tray 21, so that the storage module 2 can be plugged in the storage area 11. The advantages of the U-shaped guide channel 16 and the U-shaped guide rail 26 are that there is sufficient strength and that they maintain the direction of the storage module 2.

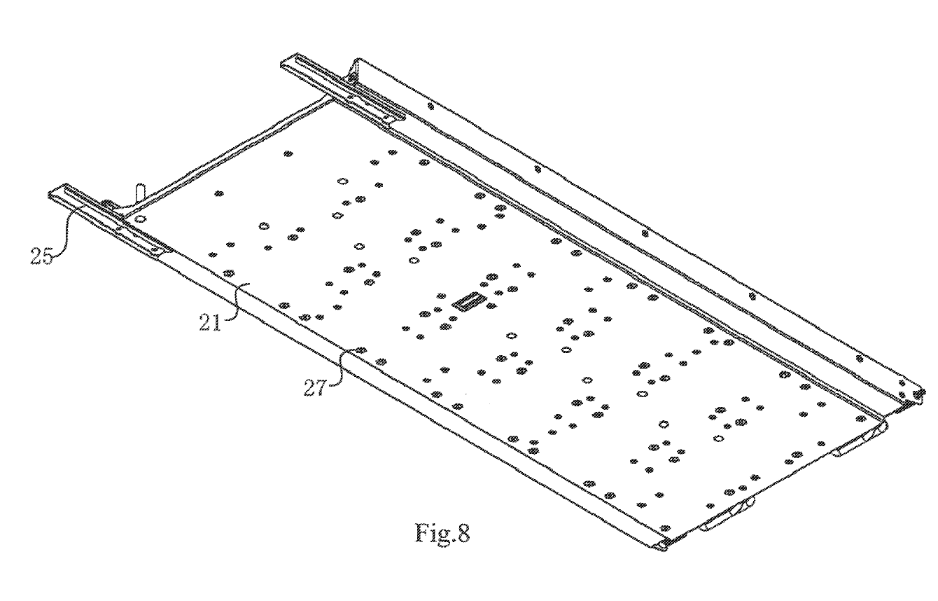

Referring to FIG. 8, a plurality of balls 27 are disposed on the bottom and the sides and bottom of the tray 21. A friction between the tray 21 and the chassis 1 is reduced by balls 27 when the grooves 25 are slid on the rails 14. The friction between the tray 21 and the chassis 1 is also reduced by rolling the balls 27. The balls 27 have points of contact rather than faces of contact, thus plugging the storage module 2 can avoid large amounts of friction. In the optional embodiment, the balls 27 can be riveted on the tray 21.

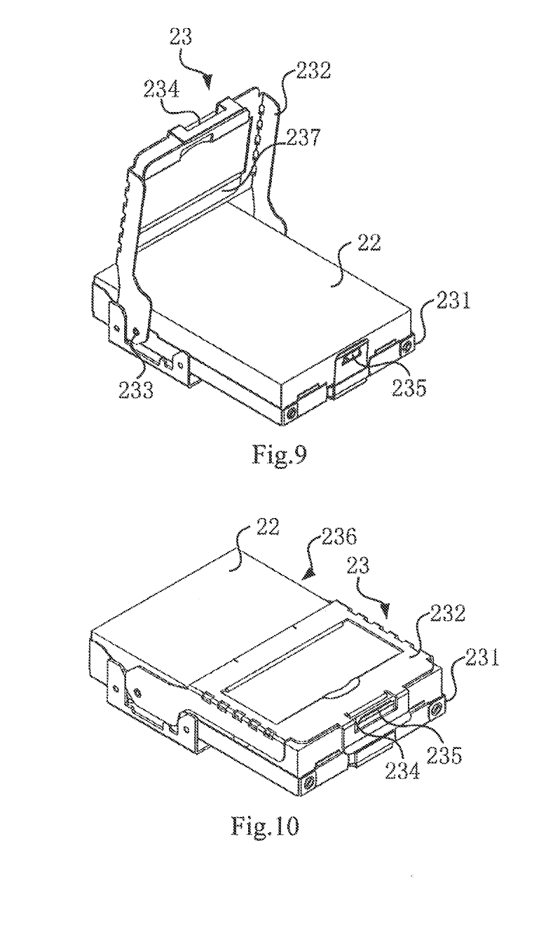

Referring to FIGS. 9 and 10, the storage boxes 23 accommodated the storage units 22 in several statuses, such as an engagement status or an unlock status.

Referring to FIGS. 9 and 10, the storage box 23 comprises an accommodated shelf 231 and an engaged shelf 232 pivoted on the accommodated shelf 231, and the storage unit is fixed in the storage box. The engaged shelf 232 is pivoted from a first position to a second position by two shafts 233 connected to the accommodated shelf 231. In the optional embodiment, the engaged shelf 232 is vertical with respect to the accommodated shelf 231 and unlocked that is the first position. A hole 234 is disposed on a front end of the engaged shelf 232, and a buckle 235 is disposed on the accommodated shelf 231. The buckle 235 is buckled to the hole 234 when the engaged shelf 232 is pivoted to the second position to fix the storage unit 22 in the storage box 23.

Referring to FIG. 10, a pierced structure 236 is disposed on a top of the storage box 23 to cool the storage unit 22. In the optional embodiment, the engaged shelf 232 does not fully cover the top of the storage box 23, and the pierced structure 236 is formed on the top of the storage box 23. Referring to FIG. 9, a buffer block 237 is disposed in the bottom (not shown), top, and/or sidewall of the storage box 23 to avoid vibrating when the data of the storage unit 22 is transmitted. In the optional embodiment, the buffer block 237 is a rubber.

Referring to FIGS. 1 and 2A, the motherboard module 3 is disposed on the front end of the motherboard area 12. The motherboard module 3 is disposed in the motherboard area 12, thus the cable is directly connected to the motherboard module 3 and a cable management device located on the front end of the case. The cable is unplugged and the server is replaced when the motherboard module 3 breaks down. The storage module 2 is pulled out and the storage unit 22 is replaced when storage module 2 breaks down, thus the server is not affected.

The adapter board 4 is disposed in the motherboard area 12 and electrically connects to the motherboard module 3. In the optional embodiment, the adapter board 4 is fixed in the motherboard area 12 near the motherboard module 3 for connecting to the motherboard module 3.

The power supply board 5 is disposed in a rear end of the motherboard area 12 and electrically connects to an external case power-supply for supplying power to the motherboard module 3 and the storage module 2. The power supply board 5 is fixed in the rear end of the motherboard area 12. The power supply board 5 does not disconnect from the external case power-supply when the storage module 2 is plugged. Thus, the power supply board 5 can continue supplying power to the server.

The signal board 6 is disposed in a rear end of the motherboard area 12 and electrically connects to an external case controller for transmitting signals of the server. The signal board 6 is fixed in the rear end of the motherboard area 12. The signal board 6 does not disconnect to the external case controller when the storage module 2 is plugged. Thus, the signal board 6 can continue to transmit the signal to the server. In the optional embodiment, the power supply board 5 and the signal board 6 are parallel to each other.

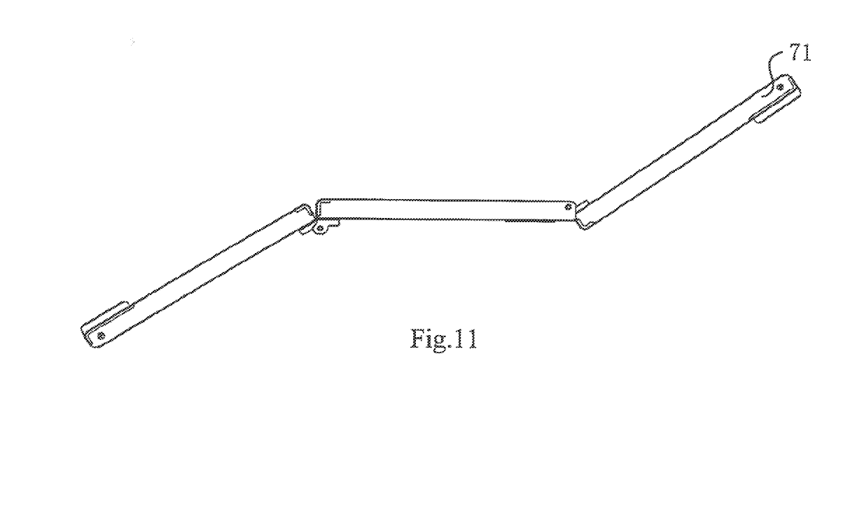

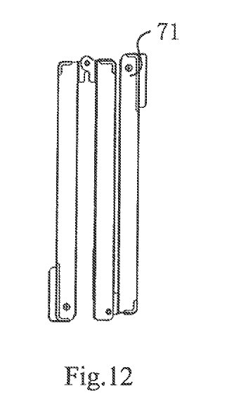

Referring to FIGS. 2A, 2B, 11, and 12, the foldable cable management module 7 comprises a foldable cable management shelf 71 and a cable 72. The cable 72 is not shown in FIG. 2B. The cable 72, the storage module 2, motherboard module 3, and the adapter board 4 are schematic to illustrate the features of the structure of the foldable cable management module 7 in FIG. 2B. The cable 72 is constrained in the foldable cable management shelf 71. In the optional embodiment, a cable management shelf with three sections is folded or unfolded by a pivoting joint. Thus the foldable cable management shelf 71 can be folded or unfolded to fix the cable 72 in different positions.

An end of the foldable cable management shelf 71 is connected to a rear end of the storage area 11, and another end of the foldable cable management shelf 71 is connected to the storage module 2. The storage module 2 can drive the foldable cable management shelf 71 to fold or unfold when the storage module 2 is plugged along the storage area 11. An end of the cable 72 is electrically connected to the storage module 2, and another end of the cable 72 is electrically connected to the motherboard module 3 and the adapter board 4, thus the storage module 2 is connected to the motherboard module 3 and the adapter board 4.

The cable 72 is constrained by the foldable cable management shelf 71 to reduce air resistance, and to meet the needs of plugging the storage module 2 in several times.

The motherboard module 3 and the adapter board 4 are connected to the power supply board 5 and the signal board 6, thus the motherboard module 3 can control the storage module 2.

The disclosure has been described with optional embodiments thereof and it is understood that many changes and modifications to the described embodiments can be carried out without departing from the scope and the spirit of the invention that is intended to be limited only by the appended claims.

What is claimed is:

1. A server disposed in a case comprising:
a chassis divided to a storage area and a motherboard area by a partition plate;
a storage module disposed in a front end of the storage area and plugged in an inner wall of the storage area;
a motherboard module disposed in a front end of the motherboard area;
an adapter board disposed in the motherboard area and electrically connected to the motherboard module;
a power supply board disposed in a rear end of the motherboard area and electrically connected to an external case power-supply for supplying power to the motherboard module and the storage module;
a signal board disposed in a rear end of the motherboard area and electrically connected to an external case controller for transmitting signals of the server; and
a foldable cable management module comprising a foldable cable management shelf and a cable constrained in the foldable cable management shelf, wherein an end of the foldable cable management shelf is connected to a rear end of the storage area, and another end of the foldable cable management shelf is connected to the storage module, an end of the cable is electrically connected to the storage module, and another end of the cable is electrically connected to the motherboard module and the adapter board;
wherein the foldable cable management shelf is folded or unfolded by plugging the storage module.

2. The server according to claim 1, wherein the storage module comprises a tray, a plurality of storage units, a plurality of storage boxes, and a storage backplane, and the tray is accommodated the storage units, the storage boxes, and the storage backplane, and the storage units are plugged from the storage backplane by the storage boxes.

3. The server according to claim 2, wherein a bottom of the tray comprises two symmetrical grooves positioned in two opposite sides relatively, and the storage area of the chassis comprises two rails slid onto the grooves.

4. The server according to claim 3, wherein a plurality of balls are disposed on the bottom and the sides of the tray, a friction between the tray and the chassis is reduced by the plurality of balls when the grooves are slid on the rails.

5. The server according to claim 3, wherein a plurality of elastic components are disposed on the front end or rear end of the bottom of the storage area, the storage module is buffered when the storage module is plugged from the storage area.

6. The server according to claim 2, wherein the tray comprises a U-shaped guide rail, and the chassis comprises a U-shaped guide channel embedded with the U-shaped guide rail, so that the storage module is plugged from the storage area.

7. The server according to claim 2, wherein a buffer block is disposed in the bottom, top and/or sidewall of the storage box.

8. The server according to claim 2, wherein the storage box comprises an accommodated shelf and an engaged shelf pivoted on the accommodated shelf, and the storage unit is fixed in the storage box.

9. The server according to claim 2, wherein a pierced structure is disposed in a top of the storage box to cool the storage unit.

10. The server according to claim 1, wherein the storage module is connected to the power supply board and the signal board via the motherboard module and the adapter board.
